(19) United States
(12) Patent Application Publication
(10) Pub. No.: US 2026/0179666 A1
(43) Pub. Date: Jun. 25, 2026

(54) DATA ALIGNMENT CIRCUIT OF MEMORY DEVICE

(71) Applicant: Winbond Electronics Corp., Taichung City (TW)

(72) Inventor: Yong Ju Kim, Zhubei City (TW)

(73) Assignee: Winbond Electronics Corp., Taichung City (TW)

(21) Appl. No.: 19/000,752

(22) Filed: Dec. 24, 2024

(51) Int. Cl. G11C 7/22; H03L 7/00

(52) U.S. Cl. CPC G11C 7/222; H03L 7/00

(57) ABSTRACT

A data alignment circuit of a memory device is provided. The data alignment circuit includes a data strobe (DQS) circuit, a synchronous control circuit and data aligners. The DQS circuit generates an output DQS signal. The synchronous control circuit generates a synchronous control clock according to at least one device clock of the memory device and the output DQS signal, and generates an output control signal according to the synchronous control clock and the output DQS signal. Each of the data aligners samples a data according to the output DQS signal respectively and outputs an output data according to the synchronous control clock and the output control signal respectively.

### BACKGROUND

### Technical Field

The disclosure generally relates to a data alignment circuit, and more particularly to a data alignment circuit of a memory device.

### Description of Related Art

Generally, a memory device includes a data alignment circuit. The data alignment circuit includes data aligners. Each of the data aligners receives a data strobe (DQS) signal and generates an output control signal according to the DQS signal, and selectively provides output data based on DQS signal and the output control signal. For example, each of the data aligners may provide an odd output data or even odd output data based on a logic value of the output control signal. For a low power requirement of the memory device, the data aligners need to be simplified to decrease a power consumption of the data aligners.

### SUMMARY

The disclosure provides a data alignment circuit of a memory device. The data alignment circuit has low power consumption.

In an embodiment of the disclosure, the data alignment circuit includes a data strobe (DQS) circuit, a synchronous control circuit and data aligners. The DQS circuit generates an output DQS signal. The synchronous control circuit is coupled to the DQS circuit. The synchronous control circuit generates a synchronous control clock according to at least one device clock of the memory device and the output DQS signal, and generates an output control signal according to the synchronous control clock and the output DQS signal. The data aligners are coupled to the DQS circuit and the synchronous control circuit. Each of the data aligners samples a data according to the output DQS signal respectively and outputs an output data according to the synchronous control clock and the output control signal respectively.

Based on the above description, the synchronous control circuit generates the output control signal and provides to the output control signal to the data aligners. The data aligners do not generate the output control signal. Therefore, the power consumptions of the data aligners can be decreased. In this way, the power consumption of the data alignment circuit can be decreased.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 illustrates a schematic diagram of a data alignment circuit according to an embodiment of the disclosure.

FIG. 2 illustrates a schematic diagram of a data aligner according to an embodiment of the disclosure.

FIG. 3 illustrates a schematic diagram of a data aligner according to an embodiment of the disclosure.

FIG. 4 illustrates a schematic diagram of a data alignment circuit according to an embodiment of the disclosure.

FIG. 5 illustrates a schematic diagram of a data alignment circuit according to an embodiment of the disclosure.

FIG. 6 illustrates a schematic diagram of an output control signal generator according to an embodiment of the disclosure.

FIG. 7 illustrates a timing diagram of a device clock, a synchronous control clock, an output DQS signal and a trigger DQS signal according to an embodiment of the disclosure.

### DESCRIPTION OF THE EMBODIMENTS

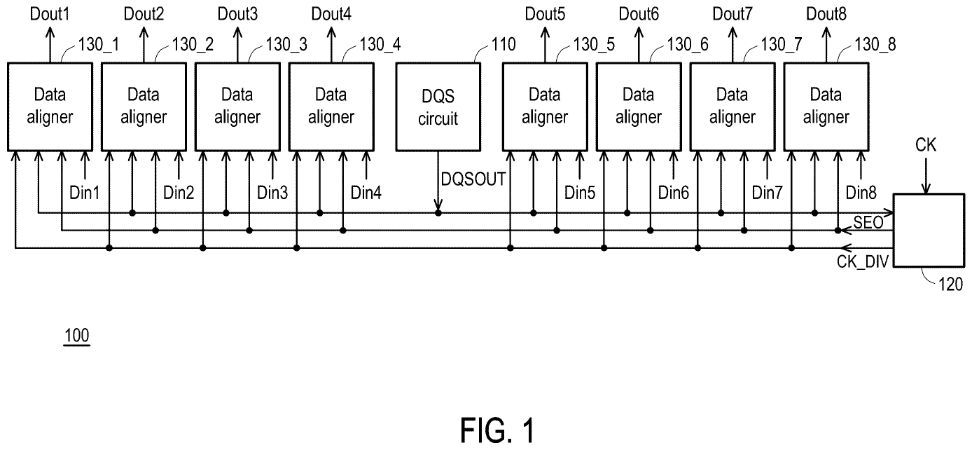

Please refer to FIG. 1, the data alignment circuit 100 of a memory device includes a data strobe (DQS) circuit 110, a synchronous control circuit 120 and data aligners 130_1 to 130_8. The memory device may be any type of dynamic random-access memory (DRAM) device, but the disclosure is not limited thereto. The DQS circuit 110 generates an output DQS signal DQSOUT. The synchronous control circuit 120 is coupled to the DQS circuit 110. The synchronous control circuit 120 generates a synchronous control clock CK_DIV according to at least one device clock CK of the memory device and the output DQS signal DQSOUT. The synchronous control circuit 120 generates an output control signal SEO according to the synchronous control clock CK_DIV and the output DQS signal DQSOUT.

The data aligners 130_1 to 130_8 are coupled to the DQS circuit 110 and the synchronous control circuit 120. Each of the data aligners 130_1 to 130_8 receives a data, the output DQS signal DQSOUT, the synchronous control clock CK_DIV and the output control signal SEO. Each of the data aligners 130_1 to 130_8 samples a data according to the output DQS signal DQSOUT respectively and outputs an output data according to the synchronous control clock CK_DIV and the output control signal SEO respectively.

For example, the data aligner 130_1 samples the data Din1 according to the output DQS signal DQSOUT and outputs the output data Dout1 according to the synchronous control clock CK_DIV and the output control signal SEO. The data aligner 130_2 samples the data Din2 according to the output DQS signal DQSOUT and outputs the output data Dout2 according to the synchronous control clock CK_DIV and the output control signal SEO, and so on.

For example, each of the data aligners may 130_1 to 130_8 provide an odd output data or even odd output data based on a logic value of the output control signal SEO.

It should be noted, the data aligners 130_1 to 130_8 provide output data Dout1 to Dout8 based on the same output DQS signal DQSOUT, the same synchronous control clock CK_DIV and the same output control signal SEO. Therefore, in a writing operation of the memory device, the data aligners 130_1 to 130_8 can provide the output data Dout1 to Dout8 (that is, writing data) synchronously. Furthermore, the data aligners 130_1 to 130_8 do not generate the output DQS signal DQSOUT, the synchronous control clock CK_DIV and the output control signal SEO. Therefore, the power consumptions of the data aligners 130_1 to 130_8 can be decreased. In this way, the power consumption of the data alignment circuit 100 can also be decreased.

In the embodiment, the data alignment circuit 100 includes 8 data aligners 130_1 to 130_8, but the disclosure is not limited thereto. The data alignment circuit of the disclosure includes at least two data aligners.

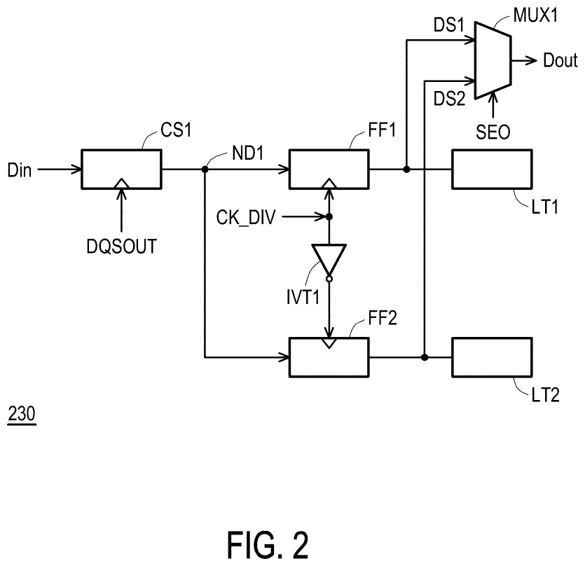

Please refer to FIG. 1 and FIG. 2,, the data aligner 230 could be used to as one of the data aligners 130_1 to 130_8 as shown in FIG. 1. In the embodiment, the data aligner 230 includes a sampling circuit CS1. The sampling circuit CS1 is coupled to the DQS circuit 110. The sampling circuit CS1 receives the data Din and the output DQS signal DQSOUT, and samples the data Din to a first node ND1 according to the output DQS signal DQSOUT. For example, when a logic value of the output DQS signal DQSOUT is a first value (for example, high logic value “1”), the sampling circuit CS1 transmits the data Din to the first node ND1. When the logic value of the output DQS signal DQSOUT is a second value (for example, low logic value “0”), the sampling circuit CS1 does not transmit the data Din to the first node ND1. In the embodiment, the sampling circuit CS1 may be implemented by a data latch circuit or a transmission gate, but the disclosure is not limited thereto.

In the embodiment, the data aligner 230 further includes flip-flops FF1, FF2, an inverter IVT1 and a multiplexer MUX1. The flip-flop FF1 is coupled to the first node ND1. The flip-flop FF1 samples the data on the first node ND1 to be a sampled data DS1 according to the synchronous control clock CK_DIV. An input terminal of the inverter IVT1 receives the synchronous control clock CK_DIV. The inverter IVT1 inverts the synchronous control clock CK_DIV to generate an inverted synchronous control clock and outputs the inverted synchronous control clock through an output terminal of the inverter IVT1. The flip-flop FF2 is coupled to the first node ND1. The flip-flop FF2 samples the data on the first node ND1 to be a sampled data DS2 according to the inverted synchronous control clock.

For example, when a logic value of the synchronous control clock CK_DIV is the first value, the flip-flop FF1 provides the sampled data DS1. The flip-flop FF2 does not provide the sampled data DS2. When the logic value of the synchronous control clock CK_DIV is the second value, the flip-flop FF1 does not provide the sampled data DS1. The flip-flop FF2 provides the sampled data DS2. In other words, the data aligner 230 provides one of the sampled data DS1 and the sampled data DS2 in response to the logic value of the synchronous control clock CK_DIV. In the embodiment, each of the flip-flops FF1 and FF2 may be implemented by a D type flip-flop (DFF), but the disclosure is not limited thereto.

In the embodiment, the multiplexer MUX1 is coupled to the flip-flops FF1, FF2. The multiplexer MUX1 outputs one of the sampled data DS1 and the sampled data DS2 to be the output data Dout according to the output control signal SEO. For example, when a logic value of the output control signal SEO is the first value, the multiplexer MUX1 selects the sampled data DS1 to be the output data Dout (for example, even output data). When the logic value of the output control signal SEO is the second value, the multiplexer MUX1 selects the sampled data DS2 to be the output data Dout (for example, odd output data).

In the embodiment, the sampling circuit CS1 is a first stage aligner of the data aligner 230. The flip-flops FF1, FF2, the inverter IVT1 and the multiplexer MUX1 is a second stage aligner of the data aligner 230.

In the embodiment, the data aligner 230 further includes latch circuits LT1 and LT2. The latch circuit LT1 is coupled to the flip-flop FF1. The latch circuit LT1 latches the sampled data DS1. The latch circuit LT2 is coupled to the flip-flop FF2. The latch circuit LT2 latches the sampled data DS2.

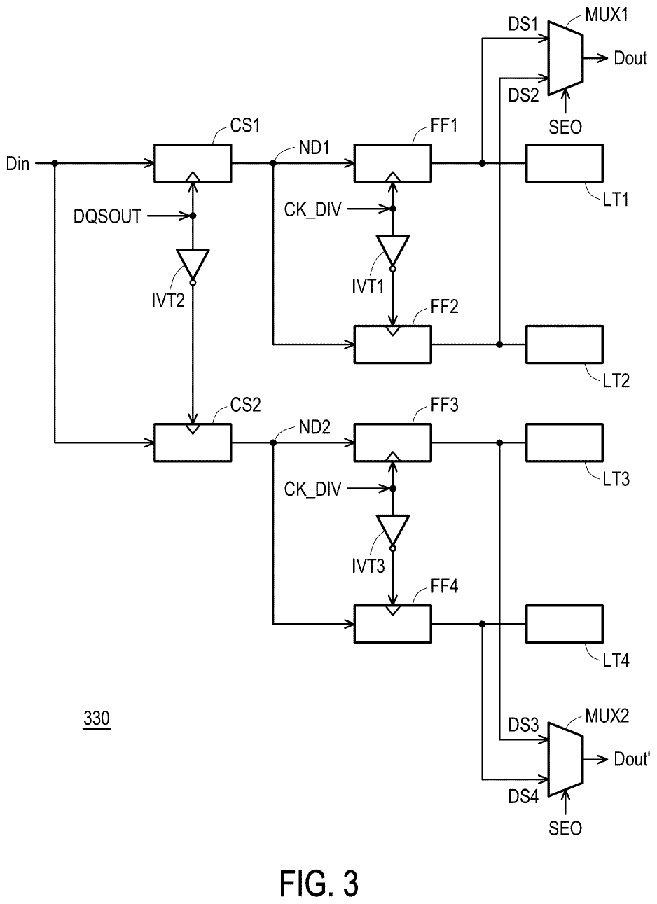

Please refer to FIG. 1 and FIG. 3, the data aligner 330 could be used to as one of the data aligners 130_1 to 130_8 as shown in FIG. 1. In the embodiment, the data aligner 330 includes sampling circuits CS1, CS2, flip-flops FF1 to FF4, inverter IVT1 to IVT3, the multiplexer MUX1 and latch circuits LT1 to LT4. The sampling circuits CS1, the flip-flops FF1, FF2, the inverter IVT1, the multiplexer MUX1 and the latch circuits LT1 and LT2 could be grouped as a first branch of the data aligner 330. The sampling circuits CS2, the flip-flops FF3, FF4, the inverter IVT3 and the latch circuits LT3 and LT4 could be grouped as a second branch of the data aligner 330.

The sampling circuits CS1, the flip-flops FF1, FF2, the inverter IVT1 and the latch circuits LT1 and LT2 have been clearly explained in the embodiments of FIG. 2, so it will not be repeated here.

In the embodiment, an input terminal of the inverter IVT2 receives the output DQS signal DQSOUT. the inverter IVT2 inverts the output DQS signal DQSOUT to generate an inverted output DQS signal and outputs the inverted output DQS signal through an output terminal of the inverter IVT2. The sampling circuit CS2 is coupled to the DQS circuit 110. The sampling circuit CS2 receives the data Din and the inverted output DQS signal, and sample the data to a second node ND2 according to the inverted output DQS signal.

For example, when the logic value of the output DQS signal DQSOUT is the first value, the logic value of the inverted output DQS signal DQSOUT is the second value. The sampling circuit CS2 does not transmit the data Din to the second node ND2. When the logic value of the output DQS signal DQSOUT is a second value, the logic value of the inverted output DQS signal DQSOUT is the first value. The sampling circuit CS2 transmits the data Din to the second node ND2. In the embodiment, the sampling circuit CS2 may be implemented by a data latch circuit or a transmission gate, but the disclosure is not limited thereto.

In the embodiment, the flip-flop FF3 is coupled to the second node ND2. The flip-flop FF3 samples the data on the second node ND2 to be a sampled data DS3 according to the synchronous control clock CK_DIV. An input terminal of the inverter IVT3 receives the synchronous control clock CK_DIV. The inverter IVT3 inverts the synchronous control clock CK_DIV to generate the inverted synchronous control clock and outputs the inverted synchronous control clock through an output terminal of the inverter IVT3. The flip-flop FF4 is coupled to the second node ND2. The flip-flop FF4 samples the data on the second node ND2 to be a sampled data DS4 according to the inverted synchronous control clock. In the embodiment, each of the flip-flops FF3 and FF4 may be implemented by a D type flip-flop (DFF), but the disclosure is not limited thereto.

For example, when the logic value of the synchronous control clock CK_DIV is the first value, the flip-flop FF3 provides the sampled data DS3. The flip-flop FF4 does not provide the sampled data DS4. When the logic value of the synchronous control clock CK_DIV is the second value, the flip-flop FF3 does not provide the sampled data DS3. The flip-flop FF4 provides the sampled data DS4. In other words, the data aligner 330 provides one of the sampled data DS3 and the sampled data DS4 in response to the logic value of the synchronous control clock CK_DIV. One of the sampled data DS3 and the sampled data DS4 is also used to be the output data Dout.

In the embodiment, the data aligner 330 further includes a multiplexer MUX2. The multiplexer MUX2 is coupled to the flip-flops FF3, FF4. The multiplexer MUX2 outputs one of the sampled data DS3 and the sampled data DS4 to be the output data Dout′ according to the output control signal SEO. For example, when a logic value of the output control signal SEO is the first value, the multiplexer MUX2 selects the sampled data DS4 to be the output data Dout′ (for example, even output data). When the logic value of the output control signal SEO is the second value, the multiplexer MUX2 selects the sampled data DS3 to be the output data Dout′ (for example, odd output data). In the embodiment, the output data Dout′ is complementary to the output data Dout.

In the embodiment, the sampling circuit CS1, CS2 and the inverter IVT2 is a first stage aligner of the data aligner 330. The flip-flops FF1 to FF4, the inverter IVT1, IVT3 and the multiplexer MUX1 is a second stage aligner of the data aligner 330.

The latch circuit LT3 is coupled to the flip-flop FF3. The latch circuit LT3 latches the sampled data DS3. The latch circuit LT4 is coupled to the flip-flop FF4. The latch circuit LT4 latches the sampled data DS4.

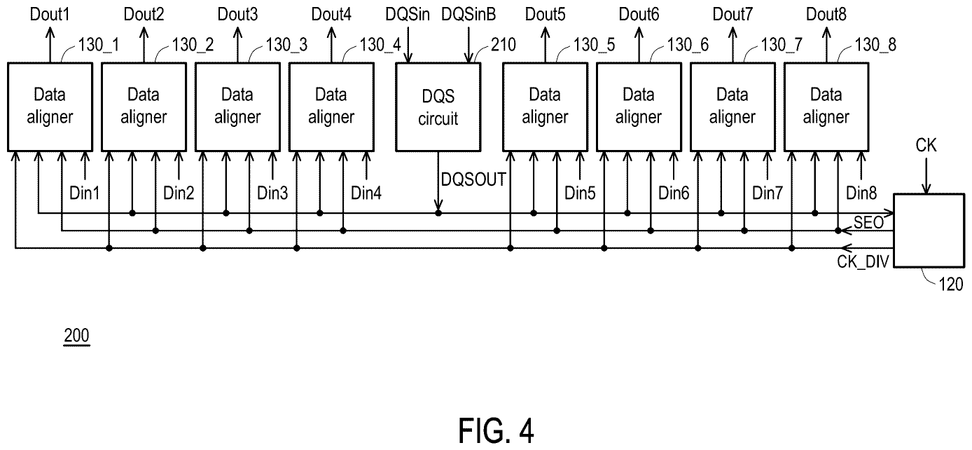

Please refer to FIG. 4, the data alignment circuit 200 includes a DQS circuit 210, the synchronous control circuit 120 and the data aligners 130_1 to 130_8. Operation of the synchronous control circuit 120 have been clearly explained in the embodiments of FIG. 1, so it will not be repeated here. Operation of each of the data aligners 130_1 to 130_8 have been clearly explained in the embodiments of FIG. 1 to FIG. 3, so it will not be repeated here.

In the embodiment, the DQS circuit 210 receives a DQS signal DQSin and a complementary DQS signal DQSinB. the DQS circuit 210 generates the output DQS signal DQSOUT according to the DQS signal DQSin and the complementary DQS signal DQSinB. The DQS signal DQSin and the complementary DQS signal DQSinB are complementary to each other. For example, the DQS circuit 210 may be implemented by a differential amplifier or a sensing amplifier, but the disclosure is not limited thereto. The output DQS signal DQSOUT is a differential signal. Thus, a risk of the output DQS signal DQSOUT being distorted by interference can be reduced.

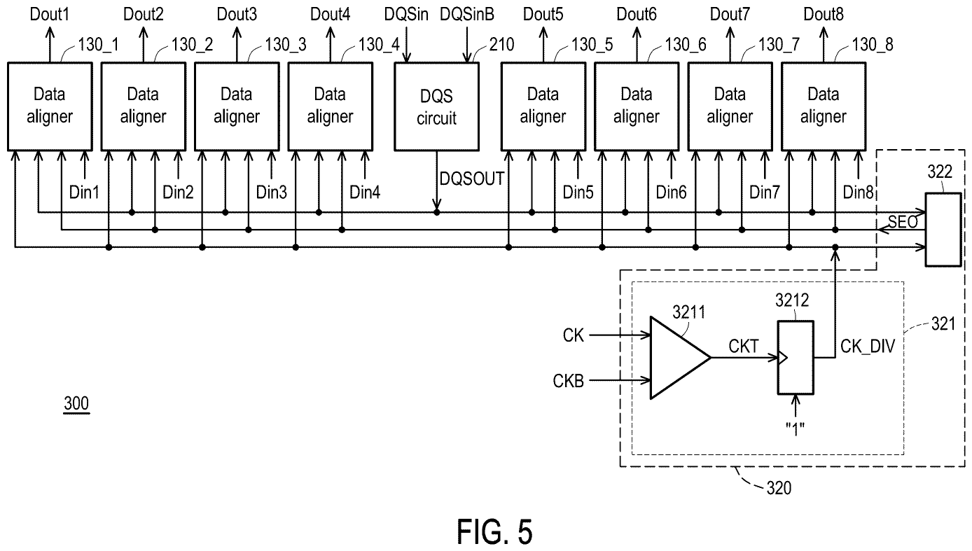

Please refer to FIG. 5, the data alignment circuit 300 includes the DQS circuit 210, a synchronous control circuit 320 and the data aligners 130_1 to 130_8. Operation of the DQS circuit 210 have been clearly explained in the embodiments of FIG. 4, so it will not be repeated here. Operation of each of the data aligners 130_1 to 130_8 have been clearly explained in the embodiments of FIG. 1 to FIG. 3, so it will not be repeated here.

In the embodiment, the synchronous control circuit 320 includes a synchronous control clock generator 321 and an output control signal generator 322. The synchronous control clock generator 321 generates the synchronous control clock CK_DIV according to the device clocks CK and CKB of the memory device. The output control signal generator 322 is coupled to the synchronous control clock generator 321. The output control signal generator 322 generates the output control signal SEO according to the synchronous control clock CK_DIV and the output DQS signal DQSOUT.

In the embodiment, the device clock CK is complementary to the device clock CKB. The synchronous control clock generator 321 includes a buffer 3211 and a trigger circuit 3212. The buffer 3211 provides a trigger clock CKT according to the device clocks CK and CKB. For example, the buffer 3211 may be implemented by a differential amplifier or a sensing amplifier, but the disclosure is not limited thereto. The trigger clock CKT is a differential clock. Thus, a risk of the trigger clock CKT being distorted by interference can be reduced.

The trigger circuit 3212 is coupled to the buffer 3211. The trigger circuit generates the synchronous control clock CK_DIV according to the trigger clock CKT. In the embodiment, the trigger circuit 3212 may be implemented by a T type flip-flop (TFF). The trigger circuit 3212 receives the trigger clock CKT through a control input terminal of the trigger circuit 3212. The trigger circuit 3212 receives the high logic value “1” through a data input terminal of the trigger circuit 3212. The trigger circuit 3212 outputs the synchronous control clock CK_DIV through a data output terminal of the trigger circuit 3212. Thus, a frequency of the synchronous control clock CK_DIV is half a frequency of the device clock CK.

In some embodiments, the trigger circuit 3212 may be implemented by other frequency dividing circuit. The disclosure is not limited by a topology of the trigger circuit 3212.

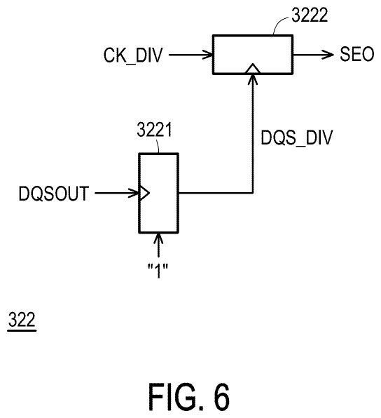

Please refer to FIG. 5 and FIG. 6, the output control signal generator 322 receives the output DQS signal DQSOUT and the synchronous control clock CK_DIV. The output control signal generator 322 generates a trigger DQS signal DQS_DIV according to the output DQS signal DQSOUT. The output control signal generator 322 decides a logic value of the output control signal SEO according to the trigger DQS signal DQS_DIV and the synchronous control clock CK_DIV.

In the embodiment, the output control signal 322 includes triggers 3221 and 3222. The trigger 3221 is coupled to the DQS circuit. The trigger 3221 generates the trigger DQS signal DQS_DIV according to the output DQS signal DQSOUT. In the embodiment, the trigger 3221 may be implemented by a T type flip-flop (TFF). The trigger 3221 receives the output DQS signal DQSOUT through a control input terminal of the trigger 3221. The trigger 3221 receives the high logic value “1” through a data input terminal of the trigger 3221. The trigger 3221 outputs the trigger DQS signal DQS_DIV through a data output terminal of the trigger circuit 3212. Thus, a frequency of the trigger DQS signal DQS_DIV is half a frequency of the output DQS signal DQSOUT.

In the embodiment, the trigger 3221 may be implemented by other frequency dividing circuit. The disclosure is not limited by a topology of the trigger 3221.

The trigger 3222 is coupled to the trigger 3221. The trigger 3222 generates the output control signal SEO according to the synchronous control clock CK_DIV and the trigger DQS signal DQS_DIV. In the embodiment, the trigger 3222 may be implemented by a D type flip-flop (DFF), but the disclosure is not limited thereto.

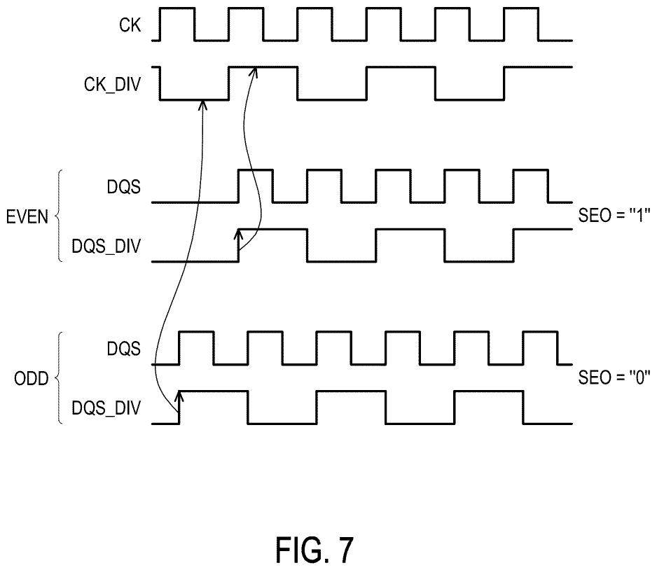

Please refer to FIG. 6 and FIG. 7, FIG. 7 illustrates the device clock CK, the synchronous control clock CK_DIV, the output DQS signal DQSOUT and the trigger DQS signal DQS_DIV. In the embodiment, when a rising edge of the trigger DQS signal DQS_DIV corresponds to a period of the first logic value of the synchronous control clock CK_DIV, the output control signal generator 322 generates the output control signal SEO having the first logic value (for example, high logic value “1”). When the rising edge of the trigger DQS signal DQS_DIV corresponds to a period of the second logic value of the synchronous control clock CK_DIV, the output control signal generator 322 generates the output control signal SEO having the second logic value (for example, low logic value “0”).

Detailly, the timing of the output DQS signal DQSOUT in an even case is different from the timing of the output DQS signal DQSOUT in an odd case. Therefore, the timing of the trigger DQS signal DQS_DIV in the even case is different from the timing of the trigger DQS signal DQS_DIV in the odd case. For example, the timing of the output DQS signal DQSOUT in the even case lags behind the timing of the output DQS signal DQSOUT in the odd case by one cycle of the output DQS signal DQSOUT. The timing of the trigger DQS signal DQS_DIV in the even case lags behind the timing of the trigger DQS signal DQS_DIV in the odd case by half cycle of the trigger DQS signal DQS_DIV. Therefore, the trigger DQS signal DQS_DIV in the even case and the trigger DQS signal DQS_DIV are complementary to each other.

In the even case, a time point of the rising edge of the trigger DQS signal DQS_DIV is in the period of the first logic value of the synchronous control clock CK_DIV. Therefore, the trigger 3222 generates the output control signal SEO having the first logic value. In the odd case, a time point of the rising edge of the trigger DQS signal DQS_DIV is in the period of the second logic value of the synchronous control clock CK_DIV. Therefore, the trigger 3222 generates the output control signal SEO having the second logic value.

Please refer to FIG. 2, FIG. 6 and FIG. 7, in the even case, a time point of the rising edge of the trigger DQS signal DQS_DIV is in the period of the first logic value of the synchronous control clock CK_DIV. Therefore, the multiplexer MUX1 selects the sampled data DS1 to be the output data Dout (that is, even output data) in response to the output control signal SEO having the first logic value. In an odd case, a time point of the rising edge of the trigger DQS signal DQS_DIV is in the period of the second logic value of the synchronous control clock CK_DIV. Therefore, the multiplexer MUX1 selects the sampled data DS2 to be the output data Dout (that is, odd output data) in response to the output control signal SEO having the second logic value.

In view of the foregoing, the data aligners provide the output data synchronously based on the same output DQS signal, the same synchronous control clock and the same output control signal. Furthermore, the data aligners do not generate the output DQS signal, the synchronous control clock and the output control signal. Therefore, the power consumptions of the data aligners can be decreased. In this way, the power consumption of the data alignment circuit 100 can also be decreased.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A data alignment circuit of a memory device, comprising:
a data strobe (DQS) circuit, configured to generate an output DQS signal;
a synchronous control circuit, coupled to the DQS circuit, and configured to generate a synchronous control clock according to at least one device clock of the memory device and the output DQS signal, and generate an output control signal according to the synchronous control clock and the output DQS signal; and
a plurality of data aligners, coupled to the DQS circuit and the synchronous control circuit, wherein each of the plurality of data aligners samples a data according to the output DQS signal respectively and outputs an output data according to the synchronous control clock and the output control signal respectively.

2. The data alignment circuit of claim 1, wherein the DQS circuit is implemented by one of a differential amplifier and a sensing amplifier.

3. The data alignment circuit of claim 1, wherein one of the plurality of data aligners comprises:
a first sampling circuit, coupled to the DQS circuit, and configured to receive the data and the output DQS signal, and sample the data to a first node according to the output DQS signal.

4. The data alignment circuit of claim 3, wherein one of the plurality of data aligners further comprises:
a first flip-flop, coupled to the first node, and configured to sample the data on the first node to be a first sampled data according to the synchronous control clock;
a first inverter, configured to invert the synchronous control clock to generate an inverted synchronous control clock;
a second flip-flop, coupled to the first node, and configured to sample the data on the first node to be a second sampled data according to the inverted synchronous control clock; and
a multiplexer, coupled to the first flip-flop and the second flip-flop, and configured to output one of the first sampled data and the second sampled data to be the output data according to the output control signal.

5. The data alignment circuit of claim 4, wherein the multiplexer selects the first sampled data to be the output data according to the output control signal having a first logic value, and selects the second sampled data to be the output data according to the output control signal having a second logic value.

6. The data alignment circuit of claim 4, wherein one of the plurality of data aligners further comprises:
a first latch circuit, coupled to the first flip-flop, and configured to latch the first sampled data; and
a second latch circuit, coupled to the second flip-flop, and configured to latch the second sampled data.

7. The data alignment circuit of claim 4, wherein one of the plurality of data aligners further comprises:
a second inverter, configured to invert the output DQS signal to generate an inverted output DQS signal; and
a second sampling circuit, coupled to the DQS circuit, and configured to receive the data and the inverted output DQS signal, and sample the data to a second node according to the inverted output DQS signal.

8. The data alignment circuit of claim 7, wherein each of the first sampling circuit and the second sampling circuit is implemented by one of a data latch circuit and a transmission gate.

9. The data alignment circuit of claim 7, wherein one of the plurality of data aligners further comprises:
a third flip-flop, coupled to the second node, and configured to sample the data on the second node to be a third sampled data according to the synchronous control clock;
a second inverter, configured to invert the synchronous control clock to generate an inverted synchronous control clock; and
a fourth flip-flop, coupled to the second node, and configured to sample the data on the second node to be a fourth sampled data according to the inverted synchronous control clock.

10. The data alignment circuit of claim 9, wherein at least one of the first flip-flop, the second flip-flop, the third flip-flop and the fourth flip-flop is implemented by a D type flip-flop.

11. The data alignment circuit of claim 9, wherein one of the plurality of data aligners further comprises:
a third latch circuit, coupled to the third flip-flop, and configured to latch the third sampled data; and
a fourth latch circuit, coupled to the fourth flip-flop, and configured to latch the fourth sampled data.

12. The data alignment circuit of claim 1, wherein the DQS circuit generates the output DQS signal according to a DQS signal and a complementary DQS signal.

13. The data alignment circuit of claim 1, wherein the synchronous control circuit comprises:
a synchronous control clock generator, configured to generate the synchronous control clock according to the at least one device clock; and
an output control signal generator, coupled to the synchronous control clock generator, and configured to generate the output control signal according to the synchronous control clock and the output DQS signal.

14. The data alignment circuit of claim 13, wherein:
the at least one device clock comprises a first device clock and a second device clock, and
the first device clock is complementary to the second device clock.

15. The data alignment circuit of claim 14, wherein the synchronous control clock generator comprises:
a buffer, configured to provide a trigger clock according to the first device clock and the second device clock; and
a trigger circuit, coupled to the buffer, and configured to generate the synchronous control clock according to the trigger clock.

16. The data alignment circuit of claim 15, wherein:
the buffer is implemented by one of a differential amplifier and a sensing amplifier, and
the trigger circuit is implemented by a T type flip-flop.

17. The data alignment circuit of claim 13, wherein the output control signal generator generates a trigger DQS signal according to the output DQS signal, and decide a logic value of the output control signal according to the trigger DQS signal and the synchronous control clock.

18. The data alignment circuit of claim 17, wherein:
when a rising edge of the trigger DQS signal corresponds to a period of a first logic value of the synchronous control clock, the output control signal generator generates the output control signal having the first logic value, and
when the rising edge of the trigger DQS signal corresponds to a period of a second logic value of the synchronous control clock, the output control signal generator generates the output control signal having the second logic value.

19. The data alignment circuit of claim 17, wherein the output control signal generator comprises:
a first trigger, coupled to the DQS circuit, and configured to generate the trigger DQS signal according to the output DQS signal; and
a second trigger, coupled to the first trigger, and configured to generate the output control signal according to the synchronous control clock and the trigger DQS signal.

20. The data alignment circuit of claim 19, wherein:
the first trigger is implemented by a T type flip-flop, and the second trigger is implemented by a D type flip-flop.
